(19) United States
(12) Patent Application Publication
(10) Pub. No.: US 2025/0130270 A1
(43) Pub. Date: Apr. 24, 2025

(54) TRANSISTOR ARRANGEMENT AND METHOD FOR MEASURING AN ON- RESISTANCE OF A TRANSISTOR ARRANGEMENT

(71) Applicant: Infineon Technologies AG, Neubiberg (DE)

(72) Inventors: Guang Zeng, München (DE); Dethard Peters, Höchstadt (DE)

(21) Appl. No.: 18/908,105

(22) Filed: Oct. 7, 2024

(30) Foreign Application Priority Data
Oct. 20, 2023 (DE) 102023128859.8

(51) Int. Cl. G01R 31/26

(52) U.S. Cl. CPC G01R 31/2621

(57) ABSTRACT

A transistor arrangement is disclosed. The transistor arrangement includes a first transistor device and a second transistor device each including a load path and a control node, and each at least partially integrated in a semiconductor body. The load paths of the first and second transistor devices are connected in parallel. The transistor arrangement further includes a first control pad connected to the control node of the first transistor device through a first resistor, and a second control pad connected to the control node of the second transistor device and connected to the first control pad through a second resistor.

### TECHNICAL FIELD

This disclosure relates in general to a transistor arrangement and a method for measuring an on-resistance of a transistor arrangement.

### BACKGROUND

The process of manufacturing power transistor devices, such as power MOSFETs, usually includes producing a plurality of power transistor devices based on a semiconductor wafer at once. Towards the end of the manufacturing process, the wafer is divided into individual semiconductor bodies (semiconductor dies) that each include at least one transistor device and that may be packaged afterwards.

In many cases it is desirable to measure the on-resistances of the transistor devices included in one wafer before dividing the wafer and packaging the semiconductor dies. This allows individual semiconductor dies to be discarded if the transistor contained therein does not meet certain on-resistance requirements, before further resources are consumed by packaging and further costs are incurred.

Measuring the on-resistances of the transistor devices on a wafer level may include using a test equipment that is capable of successively operating the individual transistor devices in an on-state and measuring the respective on resistance. In some cases, however, a parasitic resistance of the test equipment associated with the on-resistance measurement is inevitably added to the on-resistance. This parasitic resistance may result from an electrically conducting carrier (chuck) on top of which the wafer is mounted in the test equipment. The parasitic resistance added by the test equipment is usually low and, for example, in the milliohm range, so that the parasitic resistance may not negatively affect the on-resistance measurement.

The parasitic resistance, however, can become a problem if the on-resistance is in the same range as the parasitic resistance.

There is a need for a transistor arrangement that enables a relatively precise on-resistance measurement even if the on-resistance is very low, and a corresponding method.

### SUMMARY

One example relates to a transistor arrangement. The transistor arrangement includes a first transistor device and a second transistor device each including a load path and a control node and each at least partially integrated in a semiconductor body, wherein the load paths of the first transistor device and the second transistor device are connected in parallel. The transistor arrangement further includes a first control pad connected to the control node of the first transistor device through a first resistor, and a second control pad connected to the control node of the second transistor device and connected to the first control pad through a second resistor.

Another example relates to a method. The method includes determining an on-resistance of a transistor arrangement. The transistor arrangement includes a first transistor device and a second transistor device each comprising a load path and a control node and each at least partially integrated in a semiconductor body, wherein the load paths of the first transistor device and the second transistor device are connected in parallel, a first control pad connected to the control node of the first transistor device through a first resistor, and a second control pad connected to the control node of the second transistor device and connected to the first control pad through a second resistor. Determining the on-resistance includes placing the semiconductor body on an electrically conducting carrier, operating the first transistor device in an off-state, operating the second transistor device in an on-state, and measuring an electrical resistance of a circuit path that includes the parallel connected load paths of the first and second transistor devices and the carrier to obtain a first resistance, and calculating the on-resistance based on the first resistance.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates one example of a transistor arrangement that includes a first transistor device and a second transistor device that are each integrated in a semiconductor body;

FIG. 2 illustrates an equivalent circuit diagram of the transistor arrangement according to FIG. 1;

FIG. 3 illustrates a wafer including a plurality of semiconductor bodies during a measurement process using test equipment;

FIG. 4 illustrates one semiconductor body of the wafer during the measurement process in greater detail;

FIGS. 5-7 show the equivalent circuit diagram according to FIG. 2 to illustrate different measurement steps;

FIGS. 8A-8B illustrate transistor cells of the first transistor device and the second transistor device according to one example;

FIGS. 9A-9B illustrate transistor cells of the first transistor device and the second transistor device according to another example;

FIG. 10 shows a top view of the semiconductor body according to one example;

FIG. 11 shows a detail of the top view according to FIG. 10;

FIG. 12 shows a vertical cross-sectional view of the semiconductor body according to FIGS. 10 and 11 in a region in which transistor cells of the first and second transistor devices are arranged next to each other;

FIG. 13 shows a vertical cross-sectional view of the semiconductor body according to FIGS. 10 and 11 in a region in which control electrodes of the transistor cells of the first transistor device are connected to a runner;

FIG. 14 shows a vertical cross-sectional view of the semiconductor body according to FIGS. 10 and 11 in a region in which control electrodes of the transistor cells of the second transistor device are connected to a control pad;

FIG. 15 illustrates one example for implementing a first resistor connected between a first control pad and a gate runner that is connected to the control electrodes of transistor cells of the first transistor device; and

FIG. 16 illustrates one example for implementing a second resistor connected between the first control pad and a second control pad that is connected to control electrodes of transistor cells of the second transistor device.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

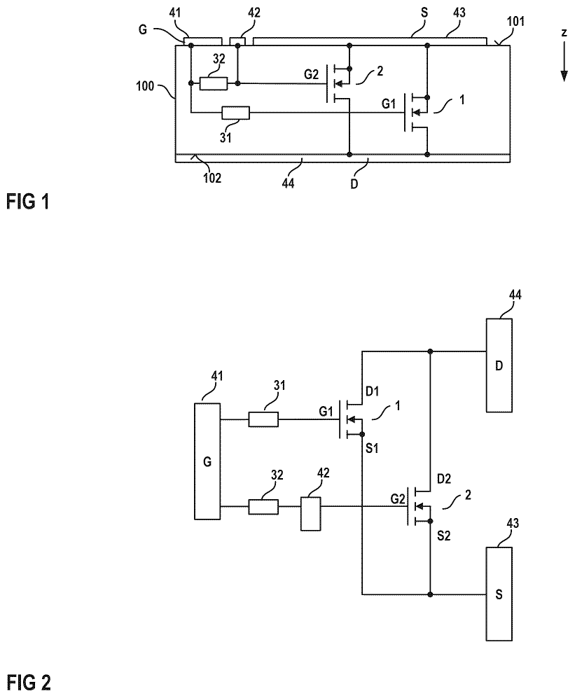

FIG. 1 schematically illustrates a transistor arrangement according to one example. The transistor arrangement includes a first transistor device 1 and a second transistor device 2 that each include a load path and a control node G1, G2. The first and second transistor devices 1, 2 are at least partially integrated in a (common) semiconductor body 100. “At least partially integrated” includes that at least active device regions of the transistor devices are integrated in the semiconductor body 100. The transistor devices may include further portions, such as electrodes, that are formed above surfaces of the semiconductor body 100.

According to one example, the semiconductor body 100 includes a monocrystalline semiconductor material. Examples of the monocrystalline semiconductor material include silicon (Si), silicon carbide (SiC), gallium arsenide (GaAs), gallium nitride (GaN), silicon germanium (SiGe), other III-V semiconductors, or germanium.

The semiconductor body 100 in which the first and second transistor devices 1, 2 are at least partially integrated is schematically illustrated in FIG. 1. The first and second transistor devices 1, 2 are represented by circuit symbols. Just for the purpose of illustration, the circuit symbols illustrated in FIG. 1 are circuit symbols of N-type enhancement (normally-off) MOSFETs. This, however, is only an example. The transistor devices 1, 2 are not restricted to be implemented as an N-type normally-on MOSFETs. Instead, the first and second transistor devices 1, 2 can be implemented as P-type devices or as normally-off devices as well. According to one example, the first and second transistor devices 1, 2 are transistor devices of the same type.

Referring to FIG. 1, the transistor arrangement further includes a first control pad 41 connected to the control node G1 of the first transistor device 1 through a first resistor 31, and a second control pad 42 connected to the control node G2 of the second transistor device 2. Furthermore, the second control pad 42 is connected to the first control pad 41 through a second resistor 32. The first and second resistors 31, 32 are represented by circuit symbols in FIG. 1.

Referring to FIG. 1, the transistor device includes a first surface 101 and a second surface 102. The second surface 102 is opposite the first surface 101 in a vertical direction z of the semiconductor body 100. The vertical direction is a direction perpendicular to the first and second surfaces 101, 102. According to one example, the first and second control pads 41, 42 are arranged above the first surface 101, as illustrated in FIG. 1. An insulating layer that may be arranged between the control pads 41, 42 and the semiconductor body 100 is not illustrated in FIG. 1.

According to one example, the load paths of the first and second transistor devices 1, 2 are circuit paths that are connected between a first load electrode 43 and a second load electrode 44. Each of the first and second load electrodes 43, 44 is common to the first and second transistor devices 1, 2.

According to one example, the first and second transistor devices 1, 2 are vertical transistor devices. In this example, as illustrated in FIG. 1, the first load electrode 43 is formed above the first surface 101 of the semiconductor body 100, and the second load electrode 44 is formed above the second surface 102 of the semiconductor body 100.

Each of the first and second control pads 41, 42 and the first and second load electrodes 43, 44 includes an electrically conducting material. Examples of the electrically conducting material include a metal, such as aluminum (Al) or copper (Cu), or an alloy, such as AlCu.

As explained herein further below, each of the first and second control pads 41, 42 is configured to be contacted by a probe needle of a test equipment in a testing process (measurement process). Thus, each of the first and second control pads 41, 42 has a size that is large enough for being contacted by a probe needle. According to one example, each of the first and second control pads 41, 42 is a planar control pad.

Furthermore, according to one example, the first control pad 41, in the finished transistor device, is configured to have a connector, such as a bond wire or a clip, connected thereto. In this example, the size of the first control pad 41 is large enough for having the connector connected thereto.

According to one example, the size of the first control pad 41 is larger than the size of the second control pad. According to one example, the size of the first control pad 41 is between 1E5 square micrometers (μm²) and 1E6 μm² (=1 square millimeter (mm₂)), and the size of the second control pad 42 is between 1E4 square micrometers (μm²) and 1E5 square micrometers (μm²). According to one example, the size of the first control pad 41 is at least 10 times the size of the second control pad 42.

Referring to the above, the first and second transistor devices 1, 2 may be implemented as MOSFETs. In this example, the control nodes G1, G2 of the first and second transistor devices 1, 2 are gate nodes, and the load paths are drain-source paths each extending between a drain node and a source node of the respective transistor device. In this example, the first and second control pads 41, 42 are gate pads, the first load electrode 43 is a source electrode or a source pad, and the second load electrode 44 is a drain electrode.

Although the first and second transistor devices 1, 2 are not restricted to be implemented as gate-controlled transistor devices, such as MOSFETs, the first and second control nodes G1, G2 are referred to as gate nodes, the first and second control pads 41, 42 are referred to as gate pads, the first load electrode 43 is referred to as source electrode 43, and the second load electrode 44 is referred to as drain electrode.

An equivalent circuit diagram of the transistor arrangement according to FIG. 1 with the first and second transistor devices 1, 2, the first and second gate pads 41, 42, the source electrode 43, and the drain electrode 44 is illustrated in FIG. 2.

Manufacturing transistor devices usually includes manufacturing a plurality of transistor devices using the same manufacturing processes at the same time. The individual transistor devices are a part of a wafer that is separated at the end of the manufacturing process in order to provide a plurality of individual semiconductor devices, which may finally be packaged. An essential feature of a transistor device is the on-resistance, which is the electrical resistance of the transistor device in the on-state. It is desirable to measure the on-resistances of the transistor devices formed on the same wafer and measure on wafer level, that is, at the end of the manufacturing process and before the wafer is separated. In this case, transistor devices that do not meet predefined requirements regarding the on-resistance can be discarded without incurring further cost by packaging, for example.

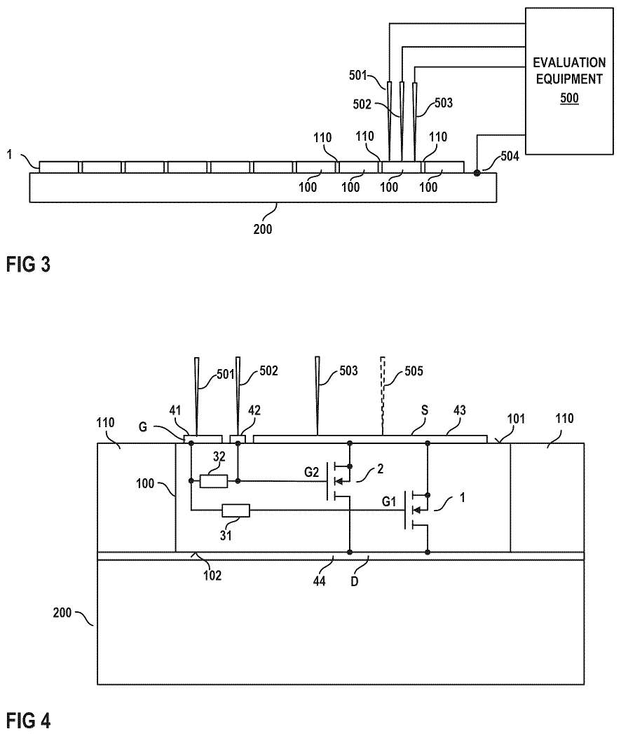

FIG. 3 schematically illustrates a wafer 1 that includes a plurality of semiconductor bodies 100 that each has a transistor arrangement of the type illustrated in FIGS. 1 and 2 at least partially integrated therein. The semiconductor bodies 100 are only schematically illustrated in FIG. 3. Contact pads, for example, are not shown. Furthermore, FIG. 3 schematically illustrates a test equipment that is configured to evaluate the individual transistor devices on a wafer level.

Referring to FIG. 3, kerf regions 110 are arranged between the semiconductor bodies 100 on the wafer 1. At the end of the manufacturing process, the wafer 1 is separated along the kerf regions 110, which are partially removed when the wafer 1 is separated.

The test equipment includes an electrically conducting carrier 200 on top of which the wafer 1 is arranged such that the second load electrodes 44 of the individual transistor devices are in contact with the carrier 200. This is illustrated in FIG. 4, which illustrates one of the semiconductor bodies 100 according to FIG. 3 in greater detail. The electrically conducting carrier 200 is also referred to as chuck in the following.

The wafer 1 may be held in place on top of the chuck 200 in various ways. According to one example, the chuck 200 includes through holes (not illustrated) and is connected to a vacuum pump (also not illustrated). The vacuum pump is configured, through the through holes, to generate a vacuum between the wafer 1 and the chuck 200 in order to hold the wafer 1 in place on top of the chuck 200.

Referring to FIGS. 3 and 4, the test equipment further includes an evaluation equipment 500 that includes probes (needles) 501, 502, 503 that are configured to be connected to the gate pads 41, 42 and the source electrode 43 during a test process (evaluation process). A first probe 501 is configured to contact the first gate pad 41, a second probe 502 is configured to contact the second gate pad 42, and a third probe 503 is configured to contact the source electrode 43 during the test process. Furthermore, the evaluation equipment 500 is connected to the chuck 200 at a position not covered by the wafer 1. An electrical contact 504 between the chuck 200 and the evaluation equipment 500 is referred to as chuck contact 504 in the following and is only schematically illustrated in FIG. 3.

Referring to the above, the first and second transistor devices 1, 2 illustrated in FIGS. 1 and 4 are vertical transistor devices, which are transistor devices in which the first and second load electrodes are formed above opposite surfaces 101, 102 of the semiconductor body 100.

Basically, the on-resistance of a vertical transistor device can be measured using a test equipment of the type illustrated in FIG. 3 by operating the transistor device in the on-state, driving a current through the load path (drain-source path) of the transistor device, and measuring a voltage drop across the load path. As can be seen from FIGS. 3 and 4, however, from the two load path electrodes only one is directly accessible. The second load electrode is covered by the chuck. A conventional way of measuring the voltage across the load path therefore includes measuring the voltage between the accessible load electrode and the chuck, and calculating the on-resistance based on the measured voltage and the current flowing through the load path.

As long as a contact resistance between the load electrode adjoining the chuck and the electrical resistance of the chuck itself is low as compared to the on-resistance the conventional method provides an acceptable result. If, however, the sum of the contact resistance and the chuck resistance is in the same range as the on-resistance the result obtained by measuring the on-resistance in the conventional way is too inaccurate.

The transistor arrangement explained before with the first and second transistor devices that have their load paths connected in parallel and that each include a control node G1, G2 connected to a respective gate pad 41, 42 makes it possible to measure the on-resistance Ron of the transistor arrangement in a more accurate way. The on-resistance Ron of the transistor arrangement is the on-resistance of the transistor arrangement when both transistor devices are in the on-state. During normal operation of the transistor device, that is, operation of the transistor device outside a test equipment both transistor devices are operated synchronously. That is, both transistor devices 1, 2 switch on or off synchronously. Thus, both transistor devices 1, 2 contribute to the conductivity of the transistor device in the on-state.

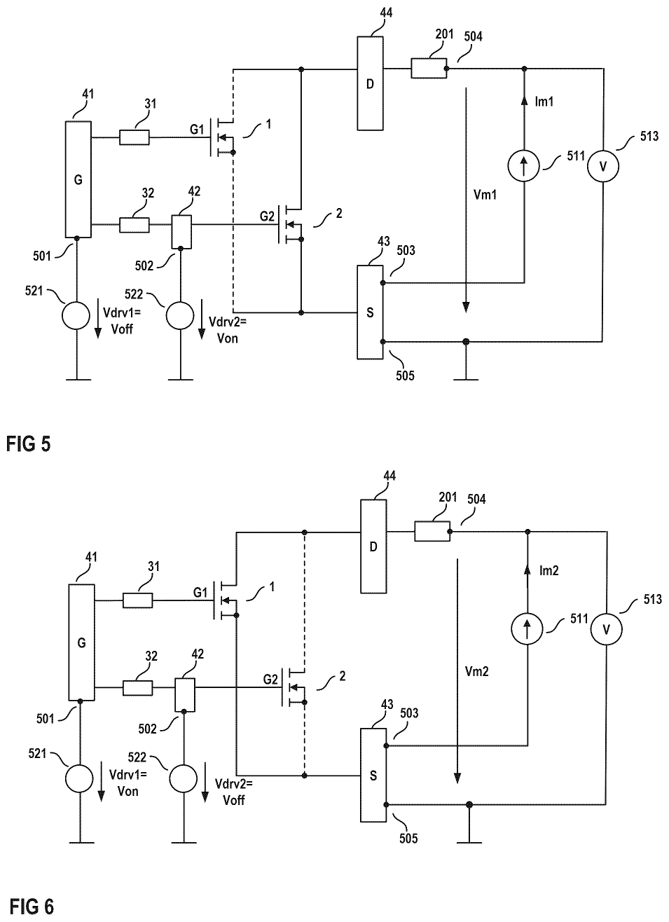

Various ways for determining the on-resistance Ron of the transistor arrangement including the first and second transistor devices 1, 2 are explained below with reference to FIGS. 5-7. Each of these figures shows the equivalent circuit diagram of the transistor arrangement during different measurement processes.

According to one example, determining the on-resistance Ron of the transistor arrangement includes operating the first transistor device 1 in an off-state (blocking state), operating the second transistor device 2 in an on-state (conducting state), and measuring an electrical resistance of a circuit path that includes the parallel connected load paths of the first and second transistor devices 1, 2 and the chuck 200 to obtain a first resistance R1. Determining the on-resistance Ron of the transistor arrangement further includes calculating the on-resistance Ron based on the first resistance R1.

The first transistor device 1 switches on or off dependent on a first drive voltage Vdrv1 received between the first gate pad 41 and the source electrode 43, wherein the first transistor device 1 is in the on-state when the first drive voltage Vdrv1 is higher than a threshold voltage of the first transistor device 1. The first transistor device 1 is in the off-state, when the first drive voltage Vdrv1 is lower than the threshold voltage. According to one example, operating the first transistor device 1 in the off-state includes applying the first drive voltage Vdrv1 having an off-level by the first probe 501 to the first gate pad 41. The first drive voltage Vdrv1 is a voltage between the probe 501 and a ground node, for example. The first drive voltage Vdrv1 is provided by a voltage source 521 of the evaluation equipment 500, for example. For applying the first drive voltage Vdrv1 between the first gate pad 41 and the source electrode 43, the source electrode 43 is also connected to the ground node, for example. The connection to the ground node may be provided by one of the probes connecting the source electrode 43 for measurement purposes in the measurement process, or may be provided by a separate probe connecting the source electrode 43 to the ground node.

The second transistor device 2 switches on or off dependent on a drive voltage Vdrv2 received between the second gate pad 42 and the source electrode 43, wherein the second transistor device 2 is in the on-state, when the drive voltage Vdrv2 is higher than a threshold voltage of the second transistor device. The second transistor device 2 is in the off-state, when the drive voltage Vdrv2 is lower than the threshold voltage. According to one example, the first and second transistor devices 1, 2 essentially have the same threshold voltages.

It should be noted that the second gate pad 42 is only used for test purposes. In the finished transistor device only the first gate pad 41 is used for driving the first and second transistor devices 1, 2. In the normal operating mode, the second gate pad 42 simply acts as a connector between the second resistor 32 and the gate node G2 of the second transistor device 2. In the normal operating mode, the first and second transistor devices 1, 2 receive the same drive voltage from the first gate pad 41. The normal operating mode is an operating mode of the transistor devices outside the test equipment and after the transistor device has been packaged, for example

According to one example, operating the second transistor device 2 in the on-state includes applying the second drive voltage Vdrv2 having an on-level by the second probe 502 to the second gate pad 42. The second drive voltage Vdrv2 is a voltage between the second gate pad 42 and the ground node, for example. The second drive voltage Vdrv2 is provided by a voltage source 522 of the evaluation equipment 500, for example.

Referring to FIG. 5 and as explained before, the second resistor 32 is connected between the first and second gate pads 41, 42. In the measurement process illustrated in FIG. 5, the second resistor 32 absorbs the difference between the first and second drive voltages Vdrv1, Vdrv2 applied to the first and second gate pads 41, 42.

According to one example illustrated in FIG. 5, measuring the first resistance R1 includes driving a predefined measurement current Im1 by a current source 511 of the evaluation equipment 500 through the circuit path including the parallel connected load paths of the first and second transistor devices 1, 2 and the chuck 200. Referring to FIG. 5, driving the measurement current Im1 includes driving the measurement current via the chuck contact 504 and the third probe 503 through the circuit path including the parallel connected load paths and the chuck 200. In the equivalent circuit diagram illustrated in FIG. 5, resistor 201 represents the contact resistance between the drain electrode 44 and the chuck 200 and the internal resistance of the chuck 200 between the drain electrode 44 and the chuck contact 504. A resistance R201 of this resistor is referred to as contact and chuck resistance in the following. Further resistances in the evaluation circuit, such as a resistance of the third probe 503 are either negligible or can be considered to be represented by the resistor 201.

Measuring the first resistance R1 further includes measuring a voltage Vm1 between the chuck contact 504 and the source electrode 43 by a voltage sensor 513 of the evaluation equipment 500. According to one example, the voltage is measured between the chuck contact 504 and a further probe 505 that is in contact with the source electrode 43 and a position spaced apart from the third probe that carries the measurement current Im. The first resistance is given by the quotient of the measured voltage Vm1 and the measurement current Im,

$$R 1 = \frac{Vm 1}{I m 1} , \qquad ( 1 )$$

and is calculated by the evaluation equipment 500 based on the measured voltage Vm1 and the measurement current Im1, for example.

When the first transistor device 1 is in the off-state and the second transistor device is in the on-state, the electrical resistance of the parallel connected load paths is essentially equal to the on-resistance Ron2 of the second transistor device 2, which is the electrical resistance of the second transistor device 2 in the on-state. The on-resistance Ron2 of the second transistor device 2 is referred to as second on-resistance in the following.

In the measurement process illustrated in FIG. 5, the measured first resistance R1 essentially equals the second on-resistance Ron2 plus the contact and chuck resistance R201,

$$R 1 = Ron 2 + R 201. \qquad ( 2 )$$

According to one example, a size of the second transistor device 2 is much smaller than a size of the first transistor device 1. The size of the second transistor device 2 is the area of active device regions of the second transistor device in the semiconductor body 100, for example. The size of the first transistor device is the area of active device regions of the first transistor device 1 in the semiconductor body 100, for example. The on-resistance of a vertical transistor device such as the first and second transistor devices 1, 2 is at least approximately inversely proportional to the area of its active device regions. This is commonly known, so that no further explanation is required in this regard.

Given that the second transistor device 2 is much smaller than the first transistor device 1, the second on-resistance Ron2 is much higher than a first on-resistance Ron1, which is the electrical resistance of the first transistor device 1 in the on-state. If, for example, m defines a ratio between the size A1 of the first transistor device 1 and the size A2 of the second transistor device 2, m=A1/A2, then the second on-resistance Ron2 is dependent on the first on-resistance Ron1 and the size ratio m as follows:

$$Ron 2 = m \cdot Ron 1. \qquad ( 3 )$$

According to one example, the size ratio m is at least 100, so that the second on-resistance Ron2 is at least 100 times the first on-resistance Ron1 (and the size of the first transistor 1 is at least 100 times the size of the second transistor 2). According to one example, the size ratio m is at least 1000 (1E3) or at least 10000 (1E4).

The on-resistance Ron of the transistor arrangement is the electrical resistance of the parallel connected load path is when both transistor devices 1, 2 are in the on-state and is given by

$$R o n = \frac{Ron 1 \cdot Ron 2}{Ron 1 + Ron 2} . \qquad ( 4 )$$

Considering equation (3), the on-resistance Ron is dependent on the first or second on-resistance Ron1, Ron2 as follows:

$$R o n = \frac{Ron 2}{m + 1} , \qquad ( 5 a )$$

$$Ron = \frac{m \cdot Ron 1}{m + 1} . \qquad ( 5 b )$$

The on-resistance Ron of the transistor arrangement is lower than the smaller one of the first and second on-resistances Ron1, Ron2. Given that the contact and chuck resistance R201 is in the same order of magnitude as the on-resistance Ron of the transistor arrangement and given that the second on-resistance Ron2 is much higher than the first on-resistance Ron1 and, therefore, the on-resistance Ron of the transistor arrangement, the contact and chuck resistance R201 is much smaller than the second on-resistance Ron2. In this case, the contact and chuck resistance R201 is negligible in equation (2), so that the measured first resistance R1 essentially equals the second on-resistance Ron2,

$$R 1 \approx Ron 2. \qquad ( 6 )$$

Referring to the above, the on-resistance Ron of the transistor arrangement is given by the electrical resistance of the parallel connected load paths of the first and second transistor devices when both transistor devices are in the on-state. Based on the first measured resistance R1, the known size ratio m and considering equations (3), (4), and (5) the on-resistance Ron of the transistor arrangement can be calculated by the evaluation equipment 500 as follows:

$$R o n = \frac{\frac{R 1}{m} \cdot R 1}{\frac{R 1}{m} + R 1} = \frac{R 1}{m + 1} . \qquad ( 7 )$$

As can be seen from equation (6), the on-resistance Ron of the transistor arrangement with the first and second transistor devices 1, 2 can be obtained by measuring the first resistance R1 and by calculating the on-resistance Ron considering the first resistance R1 and the size ratio m.

A more precise on-resistance Ron of the transistor arrangement can be obtained by measuring a second resistance R2 in addition to the first resistance R1. One example for measuring the second resistance R2 is illustrated in FIG. 6. Referring to FIG. 6, measuring the second resistance R2 includes operating the first transistor device 1 in the on-state, operating the second transistor device 2 in the off-state, and measuring an electrical resistance of the circuit path including the parallel connected load paths of the first and second transistor devices 1, 2 and the chuck 200.

Operating the first transistor device 1 in the on-state may include applying the drive voltage Vdrv1 having an on-level configured to switch on the first transistor device 1 to the first gate pad 41. Operating the second transistor device 2 in the off-state may include applying the second drive voltage Vdrv2 having an off-level configured to switch off the second transistor device 2 to the second gate pad 42. The second resistor 32 absorbs the difference between the first and second drive voltages Vdrv1, Vdrv2 in this operating state of the transistor arrangement. The second resistance R2 can be measured in the same way as the first resistance explained with reference to FIG. 5 by driving a measurement current Im2 by the current source 511 through the circuit path including the parallel connected load paths and the chuck 200 and measuring a voltage Vm2 across the second path using the voltage sensor 513. The second resistance R2 is given by the quotient of the measured voltage Vm2 and the measurement current Im2,

$$R 2 = \frac{Vm 2}{I m 2} . \qquad ( 8 )$$

Referring to equation (2) the first resistance R1 is at least approximately given by the second on-resistance Ron2 plus the chuck and contact resistance R201. Equivalently, the second resistance R2 obtained in the measurement process illustrated in FIG. 6 is at least approximately given by the first on-resistance Ron1 plus the chuck and contact resistance R201,

$$R 2 = Ron 1 + R 201. \qquad ( 9 )$$

Based on equations (2) and (8), the following relationship applies between the first and second on-resistances Ron1, Ron2 and the first and second measured resistances R1, R2,

$$R 1 - R 2 = Ron 2 - Ron 1. \qquad ( 10 )$$

Based on the relationship according to equation (10), considering the relationship between the first and second on-resistances Ron1, Ron2 according to equation (3), and considering equation (4), the on-resistance Ron is dependent on the measured first and second resistances R1, R2 and the size ratio as follows:

$$R o n = ( R 1 - R 2 ) \cdot \frac{m}{m + 1} \cdot \frac{1}{m - 1} . \qquad ( 11 )$$

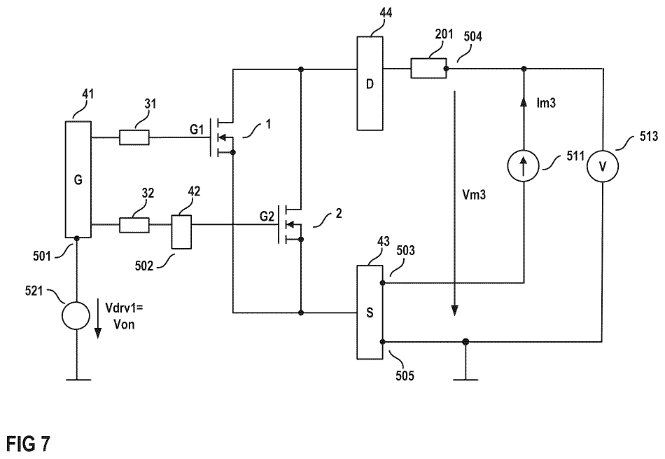

According to another example, the on-resistance Ron is obtained based on one of the measured first and second resistances R1, R2 and a measured third resistance R3. Measuring the third resistance R3 includes operating both the first transistor device 1 and the second transistor device 2 in the on-state, driving a measurement current Im3 through the circuit path including the parallel connected load paths of the first and second transistor devices 1, 2, and measuring the voltage Vm3 across the circuit path FIG. 7). Operating the first and second transistor devices 1, 2 in the on-state includes applying the first drive voltage Vdrv1 having the on-level to the first gate pad 41. In this example, both the first and second transistor devices 1, 2 are operated in the on-state based on the first drive voltage Vdrv1 received at the first gate pad 41.

The third resistance R3 is given by the quotient of the measured voltage Im3 and the measurement current Vm3,

$$R 3 = \frac{V m 2}{Im 2} . \qquad ( 11 )$$

The third resistance R3 equals the on-resistance Ron of the transistor arrangement plus the contact and chuck resistance R201,

$$R 3 = Ron + R 201 = \frac{Ron 1 \cdot Ron 2}{Ron 1 + Ron 2} + R 201. \qquad ( 12 )$$

According to one example, the on-resistance Ron is obtained based on measuring the first and third resistances R1, R3. In this example, considering equations (3) and (4), the on-resistance Ron is dependent on the first and third resistances R1, R3 and the size ratio m as follows,

$$Ron = \frac{R 1 - R 3}{m} . \qquad ( 13 )$$

According to another example, the on-resistance Ron is obtained based on measuring the second and third resistances R2, R3. In this example, considering equations (3) and (4), the on-resistance Ron is dependent on the second and third resistances R2, R3 and the size ratio m as follows,

$$Ron = ( R 2 - R 3 ) \cdot m . \qquad ( 14 )$$

According to another example, the on-resistance Ron is obtained based on the first, second, and third resistance R1, R2, R3. In this example, a more accurate result of the on-resistance Ron that is not dependent on the size ratio can be obtained. Considering equations (6), (9), and (12) it can be shown that the on-resistance Ron is given by the first and second resistances R1, R2 and the contact and chuck resistance R201 as follows,

$$Ron = \frac{1}{\frac{1}{R 2 - R 201} + \frac{1}{R 1 - {R}_{201}}} = \frac{( R 1 - R 201 ) ( R 2 - R 201 )}{R 1 + R 2 - 2 * R 201} , \qquad ( 15 a )$$

where the contact and chuck resistance R201 is dependent on the three measured resistances R1, R2, R3 as follows:

$$R 201 = R 3 - \sqrt{( R 2 - R 3 ) ( R 1 - R 3 )} . \qquad ( 15 b )$$

Thus, considering equations (15a) and (15b) an accurate value of the on-resistance Ron that is not dependent on the size ratio m can be obtained based on the three measured resistance R1, R2, R3.

Referring to the above, the contact and chuck resistance R201 is dependent on a contact resistance between the drain electrode 44 of the transistor device and the chuck 200 and dependent on a resistance of the chuck 200 itself, wherein the contact resistance may prevail. The contact and chuck resistance R201 is an indicator of how well the wafer 1 is placed on and in contact with the chuck 200. According to one example, the method includes obtaining the contact and chuck resistance R201 based on at least two of the three measured resistances R1, R2, R3.

Referring to equation (15b) an accurate value of the contact and chuck resistance R201 can be obtained based on the R1, R2, R3 measured resistances. Furthermore, based on considering equation (3) a very good approximation of the contact and chuck resistance R201 can be obtained using only two of the three measured resistances R1, R2, R3. Based on the first and second resistances R1, R2, for example, and the size ratio m, the contact and chuck resistance R201 is given by

$$R 201 = \frac{mR 2 - R 1}{m - 1} . \qquad ( 16 )$$

The obtained value of the contact and chuck resistance R201 may be used in a decision whether or not to readjust the wafer 1 on the chuck 200. According to one example, the obtained contact and chuck resistance R201 is compared with a threshold value and the wafer is readjusted when the obtained contact and chuck resistance R201 is higher than the threshold.

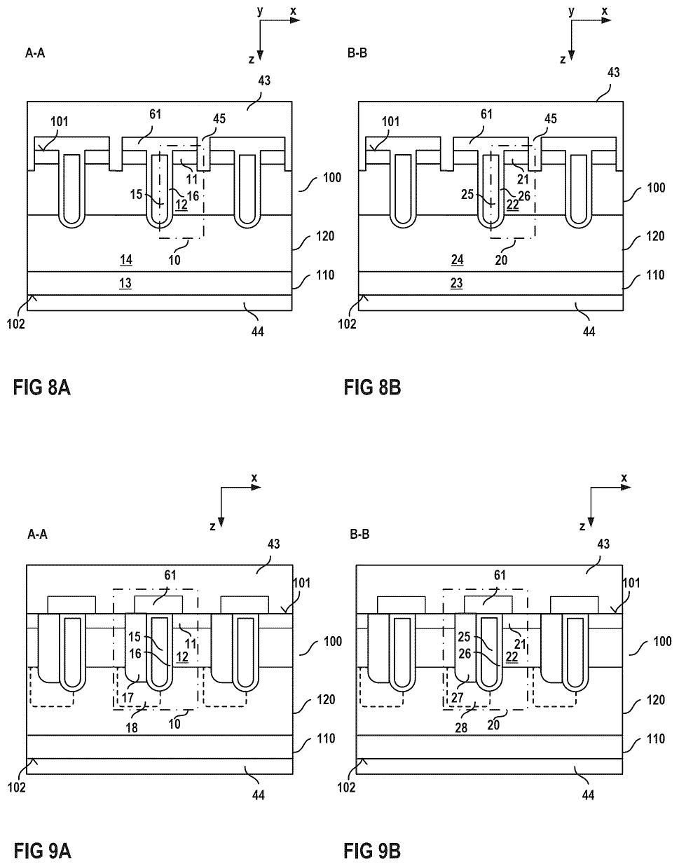

Each of the first and second transistor devices 1, 2 may include a plurality of transistor cells 10, 20. Different examples of the transistor cells 10, 20 are illustrated in FIGS. 8A-9B, wherein FIGS. 8A and 8B illustrate transistor cells 10, 20 of the first and second transistor devices 1, 2 according to one example and FIGS. 9A-9B illustrate transistor cells 10, 20 of the first and second transistor devices 1, 2 according to another example. According to one example, the transistor cells 10 of the first transistor device 1 and transistor cells 20 of the second transistor device 2 are implemented in the same way.

Referring to FIGS. 8A and 8B, each transistor cell 10, 20 includes a source region 11, 21 of a first doping type, a body region 12, 22 of a second doping type complementary to the first doping type, and a control electrode 15, 25. The control electrode 15, 25, which is also referred to as gate electrode 15, 25 in the following, is adjacent to the body region 12, 22, is dielectrically insulated from the body region 12, 22 by a gate dielectric 16, 26, and is arranged in a gate trench extending from the first surface 101 of the semiconductor body 100 into the semiconductor body 100.

Referring to FIGS. 8A and 8B, source regions 11, 21 and body regions 12, 22 of two neighboring transistor cells 10, 20 may be arranged in a mesa region between neighboring gate trenches. In this example, the body regions 12, 22 of the two neighboring transistor cells 10, 20 may be formed by one contiguous doped region of the second doping type. Furthermore, two (other) neighboring transistor cells may share the gate electrode 15, 25. That is, the gate electrodes 15, 25 of two neighboring transistor cells may be formed by one contiguous electrode arranged in one gate trench. The gate electrodes 21 include an electrically conducting material. Examples of the electrically conducting material include doped polysilicon, or a metal. The gate dielectric 22 includes an oxide, for example.

In the following, transistor cells 10 of the first transistor device 2 are also referred to as first transistor cells. Equivalently, the transistor cells 20 of the second transistor device 2 are also referred to as second transistor cells.

The source regions 11, 21 and the body regions 12, 22 of the transistor cells 10, 20 are connected to the source electrode 43. In the examples illustrated in FIGS. 8A and 8B connections between the source electrode 43 and the source and body regions 11, 21, 12, 22 include electrically conducting vias 45 that extend from the source electrode 43 through an insulating layer 61 formed above the first surface 101 of the semiconductor body 100 to the source and body regions 11, 21, 12, 22. Optionally, body contact regions that are higher doped than the body regions 12, 22 are formed between the vias 45 and the body regions 12, 22 in order to provide for an ohmic contact between the vias 45 and the body regions 12, 22. Such body contact regions, however, are not illustrated in FIGS. 8A and 8B.

Referring to FIGS. 8A and 8B, each of the first and second transistor devices 1, 2 further includes a drift region 14, 24 of the first doping type. The drift region 14, 24 adjoins the body regions 12, 22 of the transistor cells 10, 20 so that PN junctions are formed between the body regions 12, 22 of the second doping type and the drift region 14, 24 of the first doping type. In the vertical direction, the drift region 14 is arranged between the body regions 12 and a drain region 13, 23. The drain region 13, 23 is of the first doping type, for example. According to one example, the drain regions 13, 23 of the first and second transistor devices 1, 2 are formed by one contiguous doped semiconductor layer 110 of the semiconductor body 100.

According to one example, the semiconductor layer 110 forming the drain regions 13, 23 is a semiconductor substrate on top of which an epitaxial layer 120 is grown in which the further active device regions such as drift regions 14, 24, source regions 11, 21, and body regions 12, 22 are formed.

Referring to FIGS. 8A and 8B, the gate electrodes 15, 25 are spaced apart from each other in a first lateral direction x of the semiconductor body 100. The first lateral direction x-ray is a direction that is essentially parallel to the first and second surfaces 101, 102. According to one example, the gate electrodes 15, 15 are implemented as stripe electrodes (elongated electrodes). In this example, the gate electrodes 15, 25, in a second lateral direction y perpendicular to the first lateral direction x, are elongated.

In the example illustrated in FIGS. 8A and 8B respective body regions 12, 22 are formed along both of two opposing sidewalls of the gate trenches. FIGS. 9A and 9B show modifications of the transistor cells 10, 20 according to FIGS. 8A and 8B.

In the example illustrated in FIGS. 9A, 9B a body region 12, 22 is formed only along one of the two opposing sidewalls of each gate trench. Along the opposite sidewall a body contact region 17, 27 is formed that extends from the first surface 101 in the vertical direction z of the semiconductor body 100. In the vertical direction z, the body contact region 17, 27 may be a spaced apart from the trench bottom of the respective gate trench, as illustrated in FIGS. 9A and 9B. According to another example (not illustrated) the body contact region 17, 27, in the vertical direction z extends beyond the trench bottom. Optionally, a JFET region 18, 28 of the second doping type adjoins the body contact region 17, 27. The body contact region 17, 27 adjoins the body region 12 of a respective transistor cell and connects the body region 12 to the source electrode 43. The optional JFET region 18, 28, together with an adjoining portion of the drift region 14, forms a JFET that pinches off and protects the gate dielectric 16, 26 against high electric fields when the transistor device is in the off-state. This is commonly known, so that no further explanation is required in this regard.

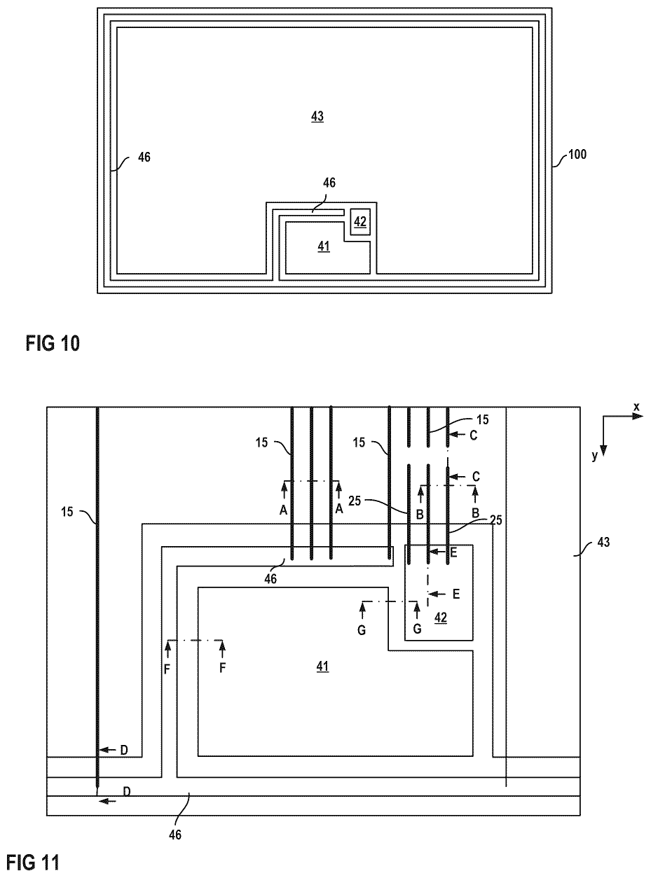

FIG. 10 shows a top view of the transistor arrangement according to one example. As explained above, the transistor arrangement includes the first gate pad 41, the second gate pad 42, and the source electrode 43. Furthermore, the transistor arrangement according to FIG. 10 includes a gate runner 46. The gate runner 46 is connected to the gate pad 41 through the first resistor 31 (which is out of view in FIG. 10). Furthermore, the gate runner 46 is connected to the gate electrodes 15 of the transistor cells 10 of the first transistor device 1. The gate electrodes 15 of the transistor cells 10 of the first transistor device 1 form the gate node G1 of the first transistor device 1. Thus, in the transistor arrangement according to FIG. 10, the first gate pad 41 is connected to the gate node G1 of the first transistor device through the first resistor 31 and the gate runner 46. One example for implementing the first resistor 31 between the first gate pad 41 and the gate runner 46 is explained herein further below.

According to one example illustrated in FIG. 10, the second gate pad 42 is arranged between the first gate pad 41 and the source electrode 43. The gate electrodes 25 of the second transistor cells 20 form the gate node G2 of the second transistor device 2. The second gate pad 42 is connected to the gate electrodes 25 of the second transistor cells 20.

The transistor cells 10, 20 are not illustrated in FIG. 10. Examples for connecting the gate electrodes 15 of the first transistor cells 10 to the gate runner 46 and for connecting the gate electrodes 25 of the second transistor cells 22 to the second gate pad 42 are explained herein further below.

FIG. 11 shows an enlarged view of the first and second gate pads 41, 42 and adjacent sections of the source electrode 43 and the gate runner 46. The first and second transistor cells 10, 20 are not illustrated in FIG. 11. For the purpose of illustration, however, the position of some gate electrodes 15 of the first transistor cells 10 below the source electrode 43 and the positions of some gate electrodes 25 of the second transistor cells 20 below the source electrode 43 are illustrated by bold lines in FIG. 11.

The transistor cells of the first and second transistor devices 1, 2 of the transistor arrangement illustrated in FIGS. 10 and 11 may correspond to the transistor cells 10, 20 according to FIGS. 8A and 8B or the transistor cells 10, 20 according to FIGS. 9A and 9B, for example. Thus, the vertical section plane A-A illustrated in FIG. 11 that cuts through some gate electrodes 15 of first transistor cells 10 may corresponds to the vertical section plane A-A illustrated in FIGS. 8A and 9A, for example. Furthermore, the vertical section plane B-B illustrated in FIG. 11 that cuts through some gate electrodes 25 of the second transistor cells 20 may correspond to the vertical section plane B-B illustrated in FIGS. 8B and 9B, for example.

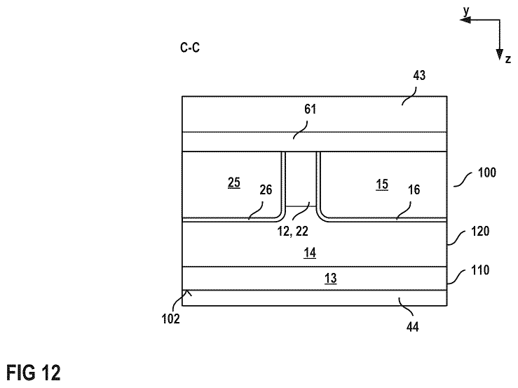

FIGS. 12-16 illustrate vertical cross-sectional views of the transistor arrangement illustrated in FIG. 11 in further vertical section planes illustrated in FIG. 11.

FIG. 12 illustrates a vertical cross-sectional view of the transistor arrangement according to FIG. 11 in section plane C-C that cuts through a portion of a gate electrode 15 of a first transistor cell 10 and an adjacent gate electrode 25 of a second transistor cell 20. In the example illustrated in FIGS. 11 and 12, a longitudinal direction of each of these gate electrodes 15, 25 corresponds to the second lateral direction y explained before.

In the example illustrated in FIG. 11, each of the gate electrodes 25 of the second transistor cells 20 are adjacent to a gate electrode 15 of a first transistor cell 10. Referring to FIG. 12, a doped region corresponding to the body regions 12, 22 of the first and second transistor cells 10, 20 is arranged between the neighboring gate electrodes 15, 25.

Each of the gate electrodes 15 of the first transistor cells 10 is connected to the gate runner 46 at least at one longitudinally end. This includes that a gate electrode 15 may be connected to the gate runner 46 at only one of its two longitudinal ends, or may be connected to the gate runner 46 at both of its longitudinal ends. Those gate electrodes 15 of the first transistor cells 10 that have one longitudinal end adjacent to gate electrodes 25 of the second transistor cells 20, for example, may be connected to the gate runner 46 at the opposing longitudinal end (which is out of view in FIG. 11), only.

In the example illustrated in FIG. 11, the gate runner 46 includes a gate runner portion that is arranged between the first gate pad 41 and the first transistor cells 10. In this example, gate electrodes 15 arranged adjacent to the first gate pad 41 may be connected to the gate runner 46 at both longitudinal ends. The portion of the gate runner 46 arranged between the first gate pad 41 and the first transistor cells 10, however, is optional and may be omitted. In this case, electrodes 15 arranged adjacent to the first gate pad 41 are connected to the gate runner 46 only at one longitudinal end, namely the longitudinal and facing away from the first gate pad 41.

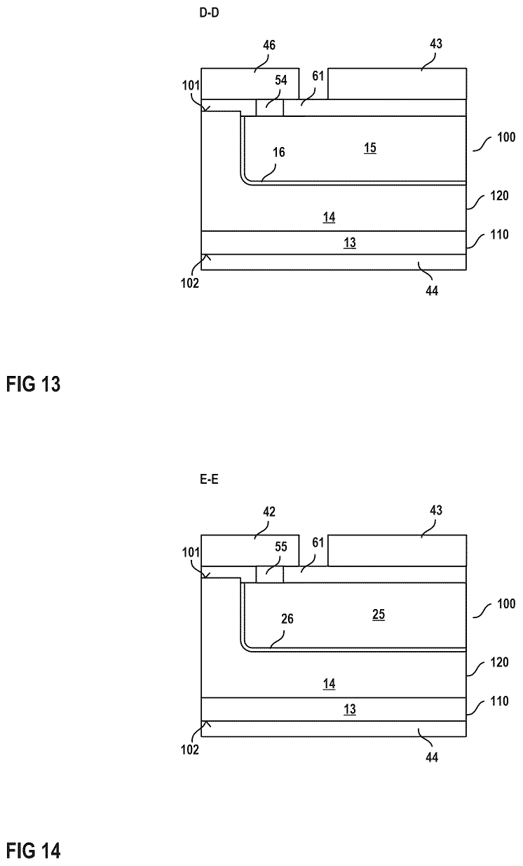

One example for connecting the gate electrodes 15 of the first transistor cells 10 to the gate runner 46 is illustrated in FIG. 13, which shows a vertical cross-sectional view of the transistor arrangement in section plane D-D illustrated in FIG. 11. Section plane D-D cuts through a portion of a gate electrode 15 of a first transistor cell 10, a portion of the gate runner 46, and a portion of the source electrode 43. In the example illustrated in FIG. 13, the gate electrode 15 is connected to the gate runner 46 through an electrically conducting via 54 that extends from the gate runner 46 through the insulating layer 61 to the gate electrode 15. For this, the gate electrode 15, in the second lateral direction y, extends below the gate runner 46.

Connecting the gate electrode 15 to the gate runner 46 in the way illustrated in FIG. 13 is only an example. Any other electrical connector extending in the insulating layer 61 from the gate runner 46 to the gate electrode 15 may be used as well. For connecting the gate electrode 15 to the gate runner 46, the gate electrode 15 not necessarily needs to extend below the gate runner 46 in the second lateral direction y. Instead, the electrical connector between the gate runner 46 and to the gate electrode 15 may extend in the second lateral direction y to a certain extent in order to connect the gate runner 46 to the gate electrode 15.

One example for connecting the gate electrodes 25 of the second transistor cells 20 to the second gate pad 42 is illustrated in FIG. 14, which shows a vertical cross-sectional view of the transistor arrangement in section plane E-E illustrated in FIG. 11. Section plane E-E cuts through a portion of a gate runner 25 of a second transistor cell 20, a portion of the second gate pad 42, and a portion of the source electrode 43. In the example illustrated in FIG. 13, the gate electrode 25 is connected to the second gate pad 42 through an electrically conducting via 54 that extends from the second gate pad 42 through the insulating layer 61 to the gate electrode 25. For this, the gate electrode 25 in the second lateral direction y extends below the second gate pad 42.

Connecting the gate electrode 25 to the second gate pad 42 in the way illustrated in FIG. 14 is only an example. Any other electrical connector extending in the insulating layer 61 from the second gate pad 42 to the gate electrode 25 may be used as well. For connecting the gate electrode 25 to the second gate pad 42, the gate electrode 25 not necessarily extends below the second gate pad 42, in the second lateral direction y. Instead, the electrical connector between the second gate pad 25 and the gate electrode 25 may extend in the second lateral direction y to a certain extent in order to connect the second gate pad 45 to the gate electrode 25.

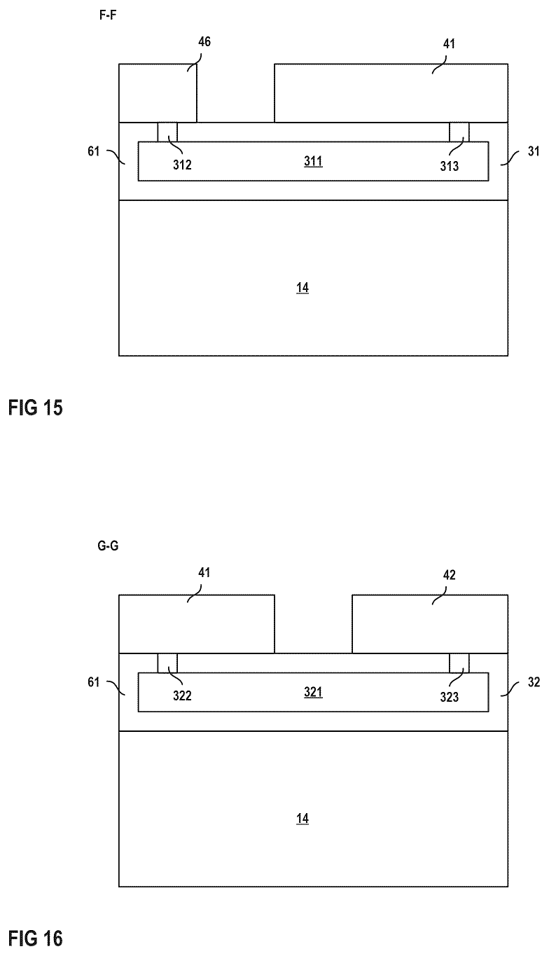

FIG. 15 illustrates one example of the first resistor 31 connected between the first gate pad 41 and the gate runner 46. More specifically, FIG. 15 illustrates a vertical cross-sectional view in section plane F-F, which cuts through a portion of the transistor arrangement in which the first resistor 31 is implemented.

Referring to FIG. 15, the first resistor 31 includes a resistive layer 311 formed in the insulating layer 61 below the first gate pad 41 and the gate runner 46. The resistive layer 311 is a doped polysilicon layer, for example. The resistive layer 311 is connected to the first gate pad 41 through a first electrically conducting via 313 and to the gate runner 46 through a second electrically conducting via 312. The first and second electrically conducting vias 313, 312 are spaced apart from each other. A resistance of the first resistor 31 can be adjusted by suitably selecting the resistivity of the resistive layer 311, a distance between the first and second electrically conducting vis 313, 312, and dimensions of the first and second electrically conducting vias in a direction perpendicular to the section plane illustrated in FIG. 15. Basically, the higher the resistivity of the resistive layer 311, the higher the resistance; the larger the distance between the conducting vias 313, 312, the higher the resistance; and the shorter the dimension of the vias 313, 312 in the direction perpendicular to the section plane illustrated in FIG. 15, the higher the resistance.

FIG. 16 illustrates one example of the second resistor 32 connected between the first and second gate pads 41, 42. More specifically, FIG. 16 illustrates a vertical cross-sectional view in section plane G-G which cuts through a portion of the transistor arrangement in which the second resistor 32 is implemented.

The second resistor 32 may be implemented similar to the first resistor 31. That is, referring to FIG. 16, the second resistor 32 may include a resistive layer 321 formed in the insulating layer below the first and second gate pads 41, 42. The resistive layer 321 is a doped polysilicon layer, for example. The resistive layer 321 is connected to the first gate pad 41 through a first electrically conducting via 322 and to the second gate pad 42 through a second electrically conducting via. Everything explained above with regard to adjusting the resistance of the second resistor 32 by suitably selecting the resistivity of the resistive layer 321, the distance between the conducting vias 322, 323 and their dimensions applies to adjusting the resistance of the second resistor 32 accordingly.

Referring to the above, in the normal operating mode of the transistor arrangement, the first and second transistor devices 1, 2 are driven by the same drive voltage applied between the first gate pad 41 and the source electrode 43. Thus, after separating the wafer 1 into the individual transistor devices and before packaging a bond wire, a clip, or the like is only connected to the first gate pad 41 to provide external access to the first gate pad 41. Referring to the above, in the normal operating mode, the drive voltage applied to the first gate pad 41 is provided to the gate node G1 of the first transistor device 1 through the first resistor 31 and to the gate node G2 of the second transistor device 2 through the second resistor 32. Referring to the above, the second resistor 32 makes it possible to apply different drive voltages to the first and second gate pad 41, 42 during the measurement process (testing process).

According to one example, in the finished transistor arrangement, a first connector, such as a bond wire or a clip, is connected to the first gate pad 41. The first connector connected to the first gate pad 41 is electrically coupled to the second gate pad 42 through the first resistor 31, so that the first connector serves for controlling both the first transistor device 1 and the second transistor device 2. Thus, for controlling operation of the second transistor device 2, a further connector in addition to the first connector and directly connected to the second gate pad 42 is not required in the transistor arrangement. Thus, in the finished transistor arrangement, one or more connectors may directly be connected only to the first gate pad 41, while the second gate pad 42 is devoid of having a connector, such as a clip or a bond wire, directly connected thereto.

According to one example, a second resistance R32 of the second resistors 32 is adapted to a first resistance R31 of the first resistor 31. According to one example, the second resistance R32 is greater than the first resistance R31. Each of the first and second transistor devices 1, 2 explained herein before includes a respective capacitance (gate-source capacitance) C1, C2 between the respective gate node G1, G2 and the source electrode 43. This capacitance C1, C2 in combination with the respective resistor R1, R2 forms an RC element that affects the switching speed of the respective transistor device 1, 2. The RC constant of the RC element of the first transistor device 1 is given by the capacitance C1 multiplied with the first resistance R31, and the RC constant of the RC element of the second transistor device 2 is given by the capacitance C2 multiplied with the second resistance R32. Basically, the lower the RC constant, the higher the switching speed.

According to one example, the first and second resistors are adapted to one another such that the first and second transistor devices 1, 2 at least approximately have the same RC constant, so that the first and second transistor devices 1, 2 at least approximately switch on and off synchronously. According to one example, this is achieved by adapting the first and second resistors 31, 32 to one another such that the second resistance R32 is proportional to the first resistance R31, with a ratio between the first and second capacitances C1, C2 being the proportionality factor,

$$R 32 = \frac{C 1}{C 2} \cdot R 31. \qquad ( 17 )$$

Basically, the greater the size of a transistor device the higher the capacitance. Furthermore, the capacitance is at least approximately proportional to the size of the respective transistor device. Taking this and taking equation (17) into account, according to one example, the second resistance R32 is proportional to the first resistance R31, with the size ratio m being the proportionality factor,

$$R 32 = m \cdot R 31. \qquad ( 18 )$$

Some of the aspects explained above are briefly summarized in the following with reference to numbered examples.

Example 1. A transistor arrangement, including: a first transistor device and a second transistor device each including a load path and a control node and each at least partially integrated in a semiconductor body, wherein the load paths of the first transistor device and the second transistor device are connected in parallel; a first control pad connected to the control node of the first transistor device through a first resistor; and a second control pad connected to the control node of the second transistor device and connected to the first control pad through a second resistor.

Example 2. The transistor arrangement according to example 1, wherein the load path of first transistor device is a circuit path between a first load electrode arranged above a first surface of the semiconductor body and a second load electrode arranged above a second surface opposite the first surface of the semiconductor body; and wherein the load path of the second transistor device is a circuit path between the first load electrode and the second load electrode.

Example 3. The transistor arrangement according to example 1 or 2, wherein the first transistor device includes a plurality of first transistor cells that each include a control electrode, wherein the second transistor device includes a plurality of second transistor cells that each include a control electrode, wherein the control node of the first transistor device is formed by the control electrodes of the first transistor cells, and wherein the control node of the second transistor device is formed by the control electrodes of the second transistor cells.

Example 4. The transistor arrangement according to example 3, wherein the control electrodes of the first transistor cells are connected to an electrically conducting gate runner formed above the first surface of the semiconductor body, and wherein the gate runner is connected to the first control pad through the first resistor.

Example 5. The transistor arrangement according to any one of examples 2 to 4, wherein the first and second control pads are formed above a first surface of the semiconductor body.

Example 6. The transistor arrangement according to example 5, wherein the first resistor is formed in an insulating layer formed above the first surface of the semiconductor body.

Example 7. The transistor arrangement according to example 6, wherein the first resistor includes a doped polysilicon layer.

Example 8. The transistor arrangement according to any one of examples 5 to 7, wherein the second resistor is formed in an insulating layer formed above the first surface of the semiconductor body.

Example 9. The transistor arrangement according to example 8, wherein the second resistor includes a doped polysilicon layer.

Example 10. The transistor arrangement according to any one of the preceding examples, wherein a ratio between a resistance of the second resistor and the first resistor at least approximately equals a ratio between a size of the first transistor device and a size of the second transistor device.

Example 11. The transistor arrangement according to any one of the preceding examples, wherein a ratio between the size of the first transistor device and the size of the second transistor device is at least 100, at least 1000, or at least 10000.

Example 12. The transistor arrangement according to any one of the preceding examples, wherein each of the first and second transistor devices is a MOSFET.

Example 13. A method, including: determining an on-resistance of a transistor arrangement, wherein the transistor arrangement includes: a first transistor device and a second transistor device each including a load path and a control node and each at least partially integrated in a semiconductor body, wherein the load paths of the first transistor device and the second transistor device are connected in parallel; a first control pad connected to the control node of the first transistor device through a first resistor; a second control pad connected to the control node of the second transistor device and connected to the first control pad through a second resistor, and wherein determining the on-resistance includes: placing the semiconductor body on an electrically conducting carrier; operating the first transistor device in an off-state, operating the second transistor device in an on-state, and measuring an electrical resistance of a circuit path that includes the parallel connected load paths of the first and second transistor devices and the carrier to obtain a first resistance; and calculating the on-resistance based on the first resistance.

Example 14. The method according to example 13, wherein operating the first transistor device in the off-state includes applying a first drive voltage having an off-level to the first control pad, and wherein operating the second transistor device in the on-state includes applying a second drive voltage having an on-level to the second control pad.

Example 15. The method according to example 13 or 14, wherein calculating the on-resistance based on the first resistance includes multiplying the first resistance by a size factor that is dependent on a ratio between a size of the second transistor device and a size of the first transistor device.

Example 16. The method according to example 15, wherein calculating the on-resistance includes calculating:

$$Ron = \frac{R 1}{m + 1} ,$$

where R1 denotes the first resistance, and m denotes the ratio between the size of the second transistor and the size of the first transistor.

Example 17. The method according to example 13 or 14, further including: operating the first transistor device in an on-state, operating the second transistor device in an off-state, and measuring an electrical resistance of a circuit path that includes the parallel connected load paths of the first and second transistor devices and the carrier to obtain a second resistance; and calculating the on-resistance further based on the second resistance.

Example 18. The method according to example 17, wherein calculating the on-resistance includes calculating:

$$Ron = ( R 1 - R 2 ) \cdot \frac{m}{m + 1} \cdot \frac{1}{m - 1}$$

where R1 denotes the first resistance, R2 denotes the second resistance, and m denotes the ratio between the size of the second transistor and the size of the first transistor.

Example 19. The method according to example 18, further including: operating each of the first transistor device and the second transistor device in an on-state, and measuring an electrical resistance of a circuit path that includes the parallel connected load paths of the first and second transistor devices and the carrier to obtain a third resistance; and calculating the on-resistance further based on the third resistance.

Example 20. The method according to example 13 or 14, further including: operating each of the first transistor device and the second transistor device in an on-state, and measuring an electrical resistance of a circuit path that includes the parallel connected load paths of the first and second transistor devices and the carrier to obtain a third resistance; and calculating the on-resistance further based on the third resistance.

Example 21. The method according to example 20, wherein calculating the on-resistance includes calculating:

$$Ron = \frac{( R 1 - R 3 )}{m}$$

where R1 denotes the first resistance, R2 denotes the second resistance, and m denotes the ratio between the size of the first transistor and the size of the second transistor.

Example 22. The method according to example 19, further including: operating the first transistor device in an on-state, operating the second transistor device in an off-state, and measuring an electrical resistance of a circuit path that includes the parallel connected load paths of the first and second transistor devices and the carrier to obtain a second resistance; and calculating the on-resistance further based on the second resistance.

Example 23. The method according to any one of examples 13 to 21, wherein the semiconductor body is part of a wafer including a plurality of semiconductor bodies.

Example 24. The method according to any one of example 13 to 22, further including: obtaining a contact and carrier resistance based on at least two measured resistances.

Example 25. The method according to example 24, further including: comparing the obtained contact and carrier resistance with a threshold and readjusting the wafer on the carrier when the obtained contact and carrier resistance is greater than the threshold.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor arrangement, comprising:
a first transistor device and a second transistor device each comprising a load path and a control node, and each at least partially integrated in a semiconductor body, wherein the load path of the first transistor device and the load path of the second transistor device are connected in parallel;
a first control pad connected to the control node of the first transistor device through a first resistor; and
a second control pad connected to the control node of the second transistor device and connected to the first control pad through a second resistor.

2. The transistor arrangement of claim 1,
wherein the load path of the first transistor device is a circuit path between a first load electrode arranged above a first surface of the semiconductor body and a second load electrode arranged above a second surface opposite the first surface of the semiconductor body, and
wherein the load path of the second transistor device is a circuit path between the first load electrode and the second load electrode.

3. The transistor arrangement of claim 1,
wherein the first transistor device comprises a plurality of first transistor cells that each include a control electrode,
wherein the second transistor device comprises a plurality of second transistor cells that each include a control electrode,
wherein the control node of the first transistor device is formed by the control electrodes of the first transistor cells, and
wherein the control node of the second transistor device is formed by the control electrodes of the second transistor cells.

4. The transistor arrangement of claim 3,
wherein the control electrodes of the first transistor cells are connected to an electrically conducting gate runner formed above the first surface of the semiconductor body, and
wherein the gate runner is connected to the first control pad through the first resistor.

5. The transistor arrangement of claim 1,
wherein the first control pad and the second control pad are formed above a first surface of the semiconductor body.

6. The transistor arrangement of claim 5,
wherein the first resistor is formed in an insulating layer formed above the first surface of the semiconductor body.

7. The transistor arrangement of claim 6,
wherein the first resistor comprises a doped polysilicon layer.

8. The transistor arrangement of claim 5,
wherein the second resistor is formed in an insulating layer formed above the first surface of the semiconductor body.

9. The transistor arrangement of claim 8,
wherein the second resistor comprises a doped polysilicon layer.

10. The transistor arrangement of claim 1,
wherein a ratio between a resistance of the second resistor and the first resistor at least approximately equals a ratio between a size of the first transistor device and a size of the second transistor device.

11. The transistor arrangement of claim 1,
wherein a ratio between a size of the first transistor device and a size of the second transistor device is at least 100, at least 1000, or at least 10000.

12. The transistor arrangement of claim 1,
wherein each of the first and second transistor devices is a MOSFET.

13. A method, comprising:
determining an on-resistance of a transistor arrangement,
wherein the transistor arrangement comprises:
a first transistor device and a second transistor device each comprising a load path and a control node, and each at least partially integrated in a semiconductor body, wherein the load path of the first transistor device and the load path of the second transistor device are connected in parallel;
a first control pad connected to the control node of the first transistor device through a first resistor;
a second control pad connected to the control node of the second transistor device and connected to the first control pad through a second resistor,
wherein determining the on-resistance comprises:
placing the semiconductor body on an electrically conducting carrier;
operating the first transistor device in an off-state, operating the second transistor device in an on-state, and measuring an electrical resistance of a circuit path that includes the parallel connected load paths of the first and second transistor devices and the carrier to obtain a first resistance; and
calculating the on-resistance based on the first resistance.

14. The method of claim 13,
wherein operating the first transistor device in the off-state comprises applying a first drive voltage having an off-level to the first control pad, and
wherein operating the second transistor device in the on-state comprises applying a second drive voltage having an on-level to the second control pad.

15. The method of claim 13,
wherein calculating the on-resistance based on the first resistance comprises multiplying the first resistance by a size factor that is dependent on a ratio between a size of the second transistor device and a size of the first transistor device.

16. The method of claim 15,
wherein calculating the on-resistance comprises calculating:
$$Ron = \frac{R 1}{m + 1} ,$$
where R1 denotes the first resistance and m denotes the ratio between the size of the second transistor and the size of the first transistor.

17. The method of claim 13, further comprising:
operating the first transistor device in an on-state, operating the second transistor device in an off-state, and measuring an electrical resistance of a circuit path that includes the parallel connected load paths of the first and second transistor devices and the carrier to obtain a second resistance; and
calculating the on-resistance further based on the second resistance.

18. The method of claim 17,
wherein calculating the on-resistance comprises calculating:
$$Ron = ( R 1 - R 2 ) \cdot \frac{m}{m + 1} \cdot \frac{1}{m - 1}$$
where R1 denotes the first resistance, R2 denotes the second resistance, and m denotes the ratio between the size of the second transistor and the size of the first transistor.

19. The method of claim 18, further comprising:
operating each of the first transistor device and the second transistor device in an on-state, and measuring an electrical resistance of a circuit path that includes the parallel connected load paths of the first and second transistor devices and the carrier to obtain a third resistance; and
calculating the on-resistance further based on the third resistance.

20. The method of claim 13, further comprising:
operating each of the first transistor device and the second transistor device in an on-state, and measuring an electrical resistance of a circuit path that includes the parallel connected load paths of the first and second transistor devices and the carrier to obtain a third resistance; and
calculating the on-resistance further based on the third resistance.

21. The method of claim 20,
wherein calculating the on-resistance comprises calculating:
$$Ron = \frac{( R 1 - R 3 )}{m}$$
where R1 denotes the first resistance, R2 denotes the second resistance, and m denotes the ratio between the size of the first transistor and the size of the second transistor.

22. The method of claim 13,
wherein the semiconductor body is part of a wafer comprising a plurality of semiconductor bodies.

23. The method of claim 13, further comprising:
obtaining a contact and carrier resistance based on at least two measured resistances.

24. The method of claim 23, further comprising:
comparing the obtained contact and carrier resistance with a threshold; and
readjusting the semiconductor body on the carrier when the obtained contact and carrier resistance is greater than the threshold.
